(19) United States
(12) Patent Application Publication
(10) Pub. No.: US 2024/0154595 A1
(43) Pub. Date: May 9, 2024

(54) ACOUSTIC WAVE DEVICE

(71) Applicant: Murata Manufacturing Co., Ltd., Nagaokakyo-shi (JP)

(72) Inventor: Katsuya DAIMON, Nagaokakyo-shi (JP)

(21) Appl. No.: 18/414,531

(22) Filed: Jan. 17, 2024

Related U.S. Application Data
(63) Continuation of application No. PCT/JP2022/025940, filed on Jun. 29, 2022.
(60) Provisional application No. 63/223,638, filed on Jul. 20, 2021.

(51) Int. Cl. H03H 9/02; H03H 9/13; H03H 9/17

(52) U.S. Cl. CPC H03H 9/02086; H03H 9/02031; H03H 9/02228; H03H 9/132; H03H 9/173; H03H 9/175; H03H 9/176

(57) ABSTRACT

An acoustic wave device includes a support including a support substrate, a piezoelectric layer on the support and including a lithium niobate layer or a lithium tantalate layer, and an IDT electrode on the piezoelectric layer and including a pair of busbars and electrode fingers. The support includes an acoustic reflector portion overlapping at least a portion of the IDT electrode in plan view. When a thickness of the piezoelectric layer is defined as d and a center-to-center distance between the electrode fingers adjacent to each other is defined as p, d/p is equal to or less than about 0.5. A region located between an intersection region and the pair of busbars is a pair of gap regions. An addition film having a higher dielectric constant and density than silicon oxide is provided in at least one of the pair of gap regions.

### CROSS REFERENCE TO RELATED APPLICATIONS

This application claims the benefit of priority to Provisional Application No. 63/223,638 filed on Jul. 20, 2021 and is a Continuation Application of PCT Application No. PCT/JP2022/025940 filed on Jun. 29, 2022. The entire contents of each application are hereby incorporated herein by reference.

### BACKGROUND OF THE INVENTION

### 1. Field of the Invention

The present invention relates to an acoustic wave device.

### 2. Description of the Related Art

Acoustic wave devices have been widely used as filters for cellular phones. In recent years, an acoustic wave device using a bulk wave in a thickness-shear mode has been proposed as described in U.S. Pat. No. 10,491,192 below. In this acoustic wave device, a piezoelectric layer is provided on a support. A pair of electrodes is provided on the piezoelectric layer. The paired electrodes are opposite to each other on the piezoelectric layer and connected to different potentials. By applying an AC voltage between the above electrodes, a bulk wave in a thickness-shear mode is excited.

International Publication No. 2016/084526 discloses an example of an acoustic wave device using a piston mode. In this acoustic wave device, an interdigital transducer (IDT) electrode is provided on the piezoelectric film. A wide portion is provided on a tip side of a plurality of electrode fingers of the IDT electrode. Accordingly, a piston mode is established by defining a plurality of regions having different acoustic velocities in a direction in which the plurality of electrode fingers extends. Thus, a transverse mode is suppressed.

### SUMMARY OF THE INVENTION

The present inventor has discovered that an acoustic wave device using a bulk wave in a thickness-shear mode uses a piston mode, which increases insertion loss.

Example embodiments of the present invention provide acoustic wave devices each capable of reducing or preventing an increase in insertion loss.

An acoustic wave device according to an example embodiment of the present invention includes a support including a support substrate, a piezoelectric layer on the support and including a lithium niobate layer or a lithium tantalate layer, and an IDT electrode on the piezoelectric layer and including a pair of busbars and a plurality of electrode fingers, in which the support includes an acoustic reflector portion overlapping at least a portion of the IDT electrode in plan view, when a thickness of the piezoelectric layer is defined as d and a center-to-center distance between the electrode fingers adjacent to each other is defined as p, d/p is equal to or less than about 0.5, some electrode fingers of the plurality of electrode fingers are connected to one busbar of the IDT electrode, remaining electrode fingers of the plurality of electrode fingers are connected to another busbar, the plurality of electrode fingers connected to the one busbar and the plurality of electrode fingers connected to the other busbar being interdigitated with each other, when viewed from a direction in which the adjacent electrode fingers are opposite to each other, a region in which the adjacent electrode fingers overlap each other is an intersection region, and a region located between the intersection region and the pair of busbars is a pair of gap regions, and an addition film with a higher dielectric constant and a higher density than silicon oxide is provided in at least one of the pair of gap regions.

According to example embodiments of the present invention, it is possible to provide acoustic wave devices each capable of reducing or preventing an increase in insertion loss.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along line I-I in FIG. 1.

FIG. 3 is a schematic cross-sectional view taken along line II-II in FIG. 1.

FIG. 4 is a schematic plan view of an acoustic wave device of a comparative example.

FIG. 5 is a schematic plan view of an acoustic wave device of a reference example.

FIG. 6 is a graph illustrating admittance frequency characteristics in the first example embodiment, the comparative example, and the reference example of the present invention.

FIG. 7 is a graph illustrating a change in admittance frequency characteristics due to a change in thicknesses of an addition film and a mass addition film.

FIG. 8 is a graph illustrating a relationship between the thickness of the addition film and the mass addition film and the admittance at 5000 MHz.

FIG. 9 is a schematic plan view of an acoustic wave device according to a second example embodiment of the present invention.

FIG. 10 is a schematic plan view of an acoustic wave device according to a third example embodiment of the present invention.

FIG. 11 is a graph illustrating a relationship between θ in Euler angles (0°, θ, 90°) and a fractional bandwidth.

FIG. 12A is a schematic perspective view illustrating an appearance of an acoustic wave device using a bulk wave in a thickness-shear mode, and FIG. 12B is a plan view illustrating an electrode structure on a piezoelectric layer.

FIG. 13 is a cross-sectional view of a portion taken along line A-A in FIG. 12A.

FIG. 14A is a schematic elevational cross-sectional view for explaining a Lamb wave propagating through a piezoelectric film of an acoustic wave device, and FIG. 14B is a schematic elevational cross-sectional view for explaining a bulk wave in a thickness-shear mode propagating through the piezoelectric film in the acoustic wave device.

FIG. 15 is a diagram illustrating an amplitude direction of a bulk wave in a thickness-shear mode.

FIG. 16 is a graph illustrating resonance characteristics of an acoustic wave device using a bulk wave in a thickness-shear mode.

FIG. 17 is a graph illustrating a relationship between d/p and the fractional bandwidth of a resonator, where p is a center-to-center distance between adjacent electrodes and d is the thickness of the piezoelectric layer.

FIG. 18 is a plan view of an acoustic wave device using a bulk wave in a thickness-shear mode.

FIG. 19 is a graph illustrating resonance characteristics of an acoustic wave device of a reference example in which spurious response appears.

FIG. 20 is a graph illustrating a relationship between the fractional bandwidth and a phase rotation amount of impedance of a spurious mode normalized by 180 degrees as magnitude of spurious emission.

FIG. 21 is a graph illustrating a relationship between d/2p and a metallization ratio MR.

FIG. 22 is an elevational cross-sectional view of an acoustic wave device including an acoustic multilayer film.

### DETAILED DESCRIPTION OF THE EXAMPLE EMBODIMENTS

The present invention will be clarified by describing specific example embodiments of the present invention with reference to the drawings.

Note that the example embodiments described in this specification are merely examples, and partial replacement or combination of configurations is possible between different example embodiments.

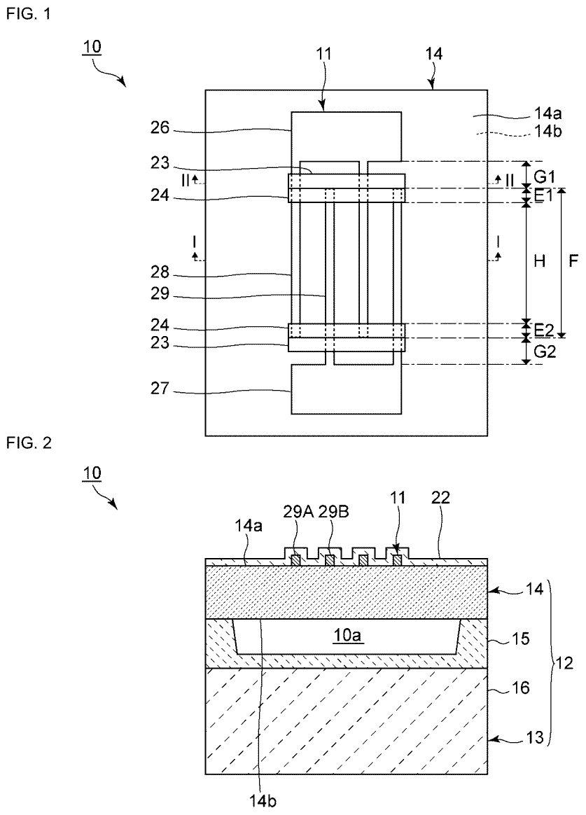

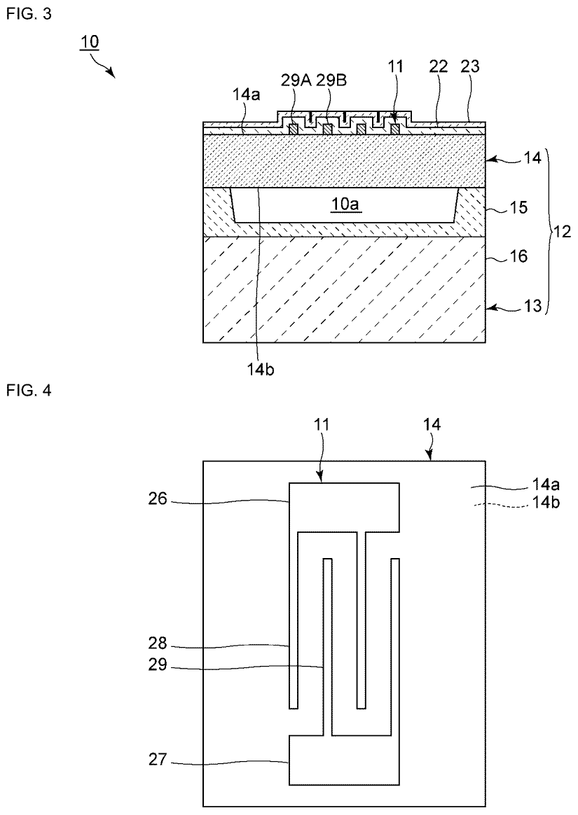

FIG. 1 is a schematic plan view of an acoustic wave device according to a first example embodiment of the present invention. FIG. 2 is a schematic cross-sectional view taken along line I-I in FIG. 1. FIG. 3 is a schematic cross-sectional view taken along line II-II in FIG. 1. Note that in FIG. 1, a dielectric film described later is omitted.

As illustrated in FIG. 1, an acoustic wave device 10 includes a piezoelectric substrate 12 and an IDT electrode 11. As illustrated in FIG. 2, the piezoelectric substrate 12 includes a support 13 and a piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. However, the support 13 may include only the support substrate 16.

The piezoelectric layer 14 includes a first main surface 14a and a second main surface 14b. The first main surface 14a and the second main surface 14b are opposite to each other. Of the first main surface 14a and the second main surface 14b, the second main surface 14b is positioned on the support 13 side.

As a material of the support substrate 16, for example, a semiconductor such as silicon, ceramics such as aluminum oxide, or the like can be used. As a material of the insulating layer 15, an appropriate dielectric such as silicon oxide or tantalum oxide can be used. The piezoelectric layer 14 is a Z-cut lithium niobate layer in the present example embodiment. More specifically, the piezoelectric layer 14 is a Z-cut-LiNbO₃ layer. However, the piezoelectric layer 14 may be a lithium niobate layer other than the Z-cut, or may be a lithium tantalate layer such as a LiTaO₃ layer.

As illustrated in FIG. 2, the support 13 includes a cavity portion 10a. More specifically, a recess is provided in the insulating layer 15. The piezoelectric layer 14 is provided on the insulating layer 15 so as to close the recess. Thus, the cavity portion 10a is defined. However, the cavity portion 10a may be provided over the insulating layer 15 and the support substrate 16, or may be provided only in the support substrate 16. Note that the cavity portion 10a may be a through-hole provided in the support 13.

The IDT electrode 11 is provided on the first main surface 14a of the piezoelectric layer 14. The acoustic wave device 10 of the present example embodiment is an acoustic wave resonator structured to generate a bulk wave in a thickness-shear mode. However, an acoustic wave device according to an example embodiment of the present invention may be a filter device including a plurality of acoustic wave resonators, a multiplexer, or the like.
In plan view, at least a portion of the IDT electrode 11 overlaps the cavity portion 10a of the support 13. In this specification, the plan view refers to a view from a direction corresponding to an upper side in FIG. 2. Note that in FIG. 2, for example, a side of the piezoelectric layer 14 of the support substrate 16 and the piezoelectric layer 14 is the upper side.

As illustrated in FIG. 1, the IDT electrode 11 includes a pair of busbars and a plurality of electrode fingers. The pair of busbars are specifically a first busbar 26 and a second busbar 27. The first busbar 26 and the second busbar 27 are opposite to each other. The plurality of electrode fingers is specifically a plurality of first electrode fingers 28 and a plurality of second electrode fingers 29. One end of each of the plurality of first electrode fingers 28 is connected to the first busbar 26. One end of each of the plurality of second electrode fingers 29 is connected to the second busbar 27. The plurality of first electrode fingers 28 and the plurality of second electrode fingers 29 are interdigitated with each other. The IDT electrode 11 may include a single-layer metal film or a laminated metal film.

Hereinafter, the first electrode finger 28 and the second electrode finger 29 may be simply referred to as electrode fingers. When a direction in which the plurality of electrode fingers extends is defined as an electrode finger extending direction and a direction in which the adjacent electrode fingers are opposite to each other is defined as an electrode finger opposing direction, the electrode finger extending direction and the electrode finger opposing direction are orthogonal to each other in the present example embodiment.

In the acoustic wave device 10, d/p is equal to or less than about 0.5, for example, where d is a thickness of the piezoelectric layer 14 and p is a center-to-center distance between adjacent electrode fingers. Thus, the bulk wave in the thickness-shear mode is preferably excited.

The cavity portion 10a of the support 13 illustrated in FIG. 2 is an acoustic reflector portion that effectively confines the energy of the acoustic wave to the piezoelectric layer 14 side. Note that an acoustic multilayer film described later may be provided as the acoustic reflector portion.

Returning to FIG. 1, the IDT electrode 11 includes an intersection region F. The intersection region F is a region in which adjacent electrode fingers overlap each other when viewed from the electrode finger opposing direction. The intersection region F includes a central region H and a pair of edge regions. The pair of edge regions are specifically a first edge region E1 and a second edge region E2. The first edge region E1 and the second edge region E2 are arranged so as to sandwich the central region H in the electrode finger extending direction. The first edge region E1 is located on the first busbar 26 side. The second edge region E2 is located on the second busbar 27 side.

The IDT electrode 11 includes a pair of gap regions. The pair of gap regions are located between the intersection region F and the pair of busbars. The pair of gap regions are specifically a first gap region G1 and a second gap region G2. The first gap region G1 is located between the first busbar 26 and the first edge region E1. The second gap region G2 is located between the second busbar 27 and the second edge region E2.

One mass addition film 24 is provided in each of the first edge region E1 and the second edge region E2. Each mass addition film 24 has a band shape, for example. Each mass addition film 24 is provided on the first main surface 14a of the piezoelectric layer 14 so as to cover the plurality of electrode fingers. Each mass addition film 24 is also provided on the first main surface 14a between the electrode fingers. The mass addition film 24 is made of tantalum oxide. Note that the material of the mass addition film 24 is not limited to the above. In this specification, the expression “a member is made of a material” includes a case where a trace amount of impurities is contained to the extent that electrical characteristics of the acoustic wave device are not significantly degraded.

The mass addition film 24 has a structure such that a low acoustic velocity region is defined in each edge region. The low acoustic velocity region is a region in which the acoustic velocity is lower than the acoustic velocity in the central region H. In the electrode finger extending direction, the central region H and the low acoustic velocity region are arranged in this order from an inner side portion to an outer side portion of the IDT electrode 11. As a result, a piston mode is established, and a transverse mode can be suppressed.

An addition film 23 is provided in each of the first gap region G1 and the second gap region G2. Each addition film 23 has a band shape, for example. Each addition film 23 is provided on the first main surface 14a of the piezoelectric layer 14 so as to cover the plurality of electrode fingers. Each addition film 23 is also provided on the first main surface 14a between the electrode fingers. The addition film 23 provided in the first gap region G1 reaches an end portion on the intersection region F side of an end portion on the first busbar 26 side and the end portion on the intersection region F side in the first gap region G1. On the other hand, the addition film 23 does not reach the end portion of the first gap region G1 on the first busbar 26 side. Similarly, the addition film 23 provided in the second gap region G2 does not reach an end portion of the second gap region G2 on the second busbar 27 side, and reaches an end portion on the intersection region F side.

In the present example embodiment, the addition film 23 is made of tantalum oxide. Although the addition film 23 and the mass addition film 24 are separately illustrated in FIG. 1, the addition film 23 and the mass addition film 24 are integrally formed of the same material in the present example embodiment. Note that the material of the addition film 23 is not limited to the above. The addition film 23 and the mass addition film 24 may be separately formed of different materials. However, the addition film 23 and the mass addition film 24 may be formed separately and may be in contact with each other.

As illustrated in FIG. 2, a dielectric film 22 is provided on the first main surface 14a of the piezoelectric layer 14 so as to cover the IDT electrode 11. Thus, the IDT electrode 11 is less likely to be damaged. In the present example embodiment, the dielectric film 22 is made of silicon oxide. However, the material of the dielectric film 22 is not limited to the above, and for example, silicon nitride, silicon oxynitride, or the like can also be used.

As illustrated in FIG. 3, the addition film 23 is provided on the dielectric film 22. Similarly, the mass addition film 24 illustrated in FIG. 1 is provided on the dielectric film 22. When the dielectric film 22 and the addition film 23 are made of the same material, a thickness of the dielectric film 22 is defined as a thickness of the dielectric film 22 in the central region H. A thickness of the addition film 23 is obtained by subtracting the thickness of the dielectric film 22 from the total thickness of the dielectric film 22 and the addition film 23. When the dielectric film 22 and the mass addition film 24 are made of the same material, a thickness of the mass addition film 24 is obtained by subtracting the thickness of the dielectric film 22 from the total thickness of the dielectric film 22 and the mass addition film 24.

The addition film 23 and the mass addition film 24 are indirectly provided on the first main surface 14a of the piezoelectric layer 14 and the plurality of electrode fingers with the dielectric film 22 interposed therebetween. However, the dielectric film 22 need not be provided. In this case, the addition film 23 and the mass addition film 24 may be provided directly on the plurality of electrode fingers and on the portion between the electrode fingers on the first main surface 14a.

One of the unique features of the present example embodiment is that the addition film 23 is provided in the pair of gap regions, and a dielectric constant and density of the addition film 23 are higher than a dielectric constant and density of silicon oxide. Thus, it is possible to reduce or prevent an increase in insertion loss. Therefore, the piston mode can be established and the transverse mode can be suppressed without increasing the insertion loss. The details will be described below by comparing the present example embodiment with the comparative example and the reference example.

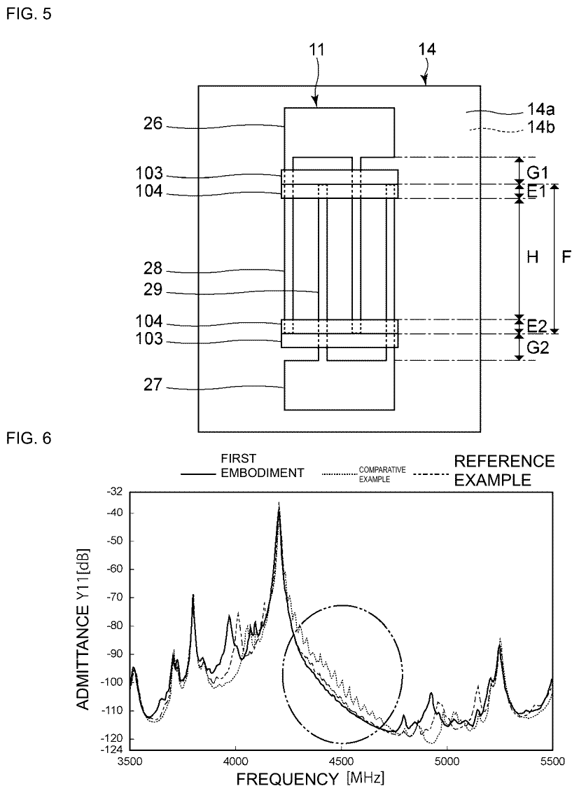

As illustrated in FIG. 4, the comparative example is different from the first example embodiment in that the addition film and the mass addition film are not provided. As illustrated in FIG. 5, the reference example is different from the first example embodiment in that an addition film 103 and a mass addition film 104 are made of silicon oxide. Admittance frequency characteristics of the acoustic wave devices of the first example embodiment, the comparative example, and the reference example were compared. Design parameters of the acoustic wave device 10 of the first example embodiment according to the comparison are as follows. Note that a wavelength defined by an electrode finger pitch of the IDT electrode 11 is denoted by λ. The electrode finger pitch is a center-to-center distance between the adjacent electrode fingers. A dimension of the gap region along the electrode finger extending direction is defined as a width of the gap region.
Piezoelectric layer; material: Z-cut-LiNbO₃, thickness: 0.36 μm
IDT electrode; layer configuration: Ti layer/AlCu layer/Ti layer from piezoelectric layer side, thickness of each layer: 0.01 μm/0.49 μm/0.004 μm from the piezoelectric layer side, wavelength λ: 8.4 μm, duty ratio: 0.21, width of gap region: 5 μm
Dielectric film; material: SiO₂, thickness: 0.108 μm
Mass addition film; material: Ta₂O₅, dimension along electrode finger extending direction: 1 μm
Addition film; material: Ta₂O₅, dimension along the electrode finger extending direction: 2.2 μm, thickness: 15 nm

Design parameters of the acoustic wave device of the comparative example are as follows.
Piezoelectric layer; material: Z-cut-LiNbO₃, thickness: 0.36 μm
IDT electrode; layer configuration: Ti layer/AlCu layer/Ti layer from piezoelectric layer side, thickness of each layer: 0.01 μm/0.49 μm/0.004 μm from the piezoelectric layer side, wavelength λ: 8.4 μm, duty ratio: 0.21, width of gap region: 5 μm
Dielectric film; material: SiO₂, thickness: 0.108 μm

Design parameters of the acoustic wave device of the reference example are as follows.
Piezoelectric layer; material: Z-cut-LiNbO₃, thickness: 0.36 μm
IDT electrode; layer configuration: Ti layer/AlCu layer/Ti layer from piezoelectric layer side, thickness of each layer: 0.01 μm/0.49 μm/0.004 μm from the piezoelectric layer side, wavelength λ: 8.4 μm, duty ratio: 0.21, width of gap region: 5 μm
Dielectric film; material: SiO₂, thickness: 0.108 μm
Mass addition film; material: SiO₂, dimension along electrode finger extending direction: 1 μm
Addition film; material: SiO₂, dimension along the electrode finger extending direction: 2.2 μm, thickness: 15 nm

FIG. 6 is a graph illustrating admittance frequency characteristics in the first example embodiment, the comparative example, and the reference example. Note that the insertion loss decreases as admittance in a band surrounded by the alternate long and two short dashes line in FIG. 6 decreases.

As illustrated in FIG. 6, it is understood that the admittance is smaller in the first example embodiment than in the comparative example and the reference example in the band surrounded by the alternate long and two short dashes line. From this, it is understood that the insertion loss can be reduced in the first example embodiment.

In the admittance frequency characteristics of the comparative example, a large ripple caused by the transverse mode is generated in the band surrounded by the alternate long and two short dashes line in FIG. 6. In contrast, in the admittance frequency characteristics of the first example embodiment, the ripple is suppressed in the band. From this, it is understood that the transverse mode can be suppressed in the first example embodiment.

The reason why the insertion loss can be reduced in the first example embodiment is considered as follows. That is, as illustrated in FIG. 1, the addition film 23 having a higher dielectric constant and a higher density than silicon oxide is provided in each gap region. Thus, it is considered that the energy of the acoustic wave can be efficiently confined, and the insertion loss can be reduced.

The acoustic wave device 10 uses not a surface acoustic wave but a bulk wave in a thickness-shear mode. In this case, even when the addition film 23 is provided in each gap region, the piston mode can be suitably established. This makes it possible to suppress both the transverse mode and an increase in insertion loss.

Here, a plurality of acoustic wave devices 10 in which the thicknesses of the addition film 23 and the mass addition film 24 were different from each other were prepared. Admittance frequency characteristics of each acoustic wave device 10 were obtained. Note that, here, in each of the acoustic wave devices 10, the addition film 23 and the mass addition film 24 have the same thickness.

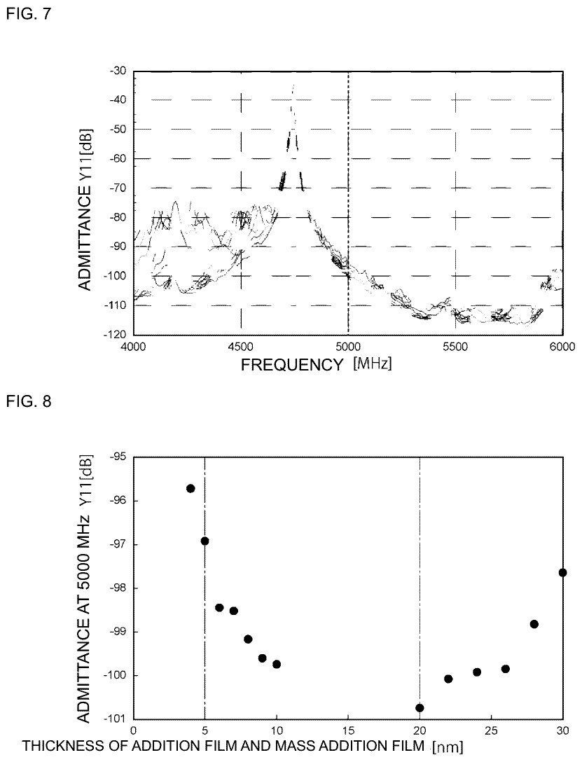

FIG. 7 is a graph illustrating a change in the admittance frequency characteristics due to a change in the thicknesses of the addition film and the mass addition film. FIG. 8 is a graph illustrating a relationship between the thickness of the addition film and the mass addition film and the admittance at 5000 MHz. Note that each waveform in FIG. 7 represents the admittance frequency characteristics of each acoustic wave device 10.

In each acoustic wave device 10 having the admittance frequency characteristics illustrated in FIG. 7, the insertion loss decreases as the admittance near 5000 MHz decreases. FIG. 8 illustrates the admittance at 5000 MHz of each acoustic wave device 10. As illustrated in FIG. 8, it is understood that the admittance can be effectively reduced when each of the thicknesses of the addition film 23 and the mass addition film 24 is equal to or larger than about 5 nm and equal to or smaller than about 20 nm, for example. Therefore, the thickness of the addition film 23 is preferably equal to or more than about 5 nm and equal to or less than about 20 nm, for example. This makes it possible to effectively reduce the insertion loss.

The addition film 23 illustrated in FIG. 1 may be provided in at least one of the first gap region G1 and the second gap region G2. However, it is preferable that the addition film 23 be provided in both the first gap region G1 and the second gap region G2. This makes it possible to more reliably reduce or prevent an increase in insertion loss.

In the first example embodiment, the addition film 23 is provided over the entire gap region in the electrode finger opposing direction. Note that the addition film 23 may be provided in at least a portion of at least one of the first gap region G1 and the second gap region G2 in the electrode finger opposing direction. For example, the addition film 23 may be provided on at least one electrode finger. However, the addition film 23 is preferably provided on the piezoelectric layer 14 so as to cover the plurality of electrode fingers in at least one of the first gap region G1 and the second gap region G2. The addition film 23 is preferably provided over the entire gap region of at least one of the first gap region G1 and the second gap region G2 in the electrode finger opposing direction. This makes it possible to more reliably reduce or prevent an increase in insertion loss.

Note that unlike the first example embodiment, for example, when the piezoelectric layer, the addition film, and the electrode fingers are stacked in this order, the electrode fingers are positioned on the piezoelectric layer in the central region or the like, and are positioned on the addition film in at least a portion of the gap region. A step portion is provided between a portion of the electrode finger positioned on the piezoelectric layer and a portion of the electrode finger positioned on the addition film. In contrast, in the first example embodiment, the piezoelectric layer 14, the electrode fingers, and the addition film 23 are stacked in this order. Therefore, the electrode finger is not provided with a step portion, and a crack starting from the step portion does not occur. Thus, the electrode fingers are less likely to be damaged.

As the material of the addition film 23, at least one dielectric selected from the group consisting of tungsten oxide, niobium pentoxide, tantalum oxide, and hafnium oxide is preferably used. This makes it possible to more reliably reduce or prevent an increase in insertion loss.

The mass addition film 24 may be provided in at least one of the first edge region E1 and the second edge region E2. However, it is preferable that the mass addition film 24 be provided in both the first edge region E1 and the second edge region E2. Thus, the transverse mode can be suppressed more reliably.

The mass addition film 24 is a tantalum oxide film in the first example embodiment. However, the material of the mass addition film 24 is not limited to the above. The mass addition film 24 may be, for example, a silicon oxide film.

A plurality of mass addition films 24 may be provided in each edge region. For example, the mass addition films 24 may be provided on only one electrode finger. Alternatively, the mass addition film 24 is not necessarily provided. When the mass addition film 24 is not provided, for example, the electrode finger having a wide portion may be provided in at least one of the first edge region E1 and the second edge region E2. The wide portion is a portion of the electrode finger having a width larger than a width of the electrode finger in the central region H. The width of the electrode finger is a dimension of the electrode finger along the electrode finger opposing direction. Also in this case, the low acoustic velocity region is defined in the edge region in which the wide portion is provided. As a result, the piston mode is established, and the transverse mode is suppressed.

In the first example embodiment, each addition film 23 reaches the end portion of each gap region on the intersection region F side, and does not reach the end portion thereof on the busbar side. However, the position of the addition film 23 in the electrode finger extending direction is not limited to the above. The addition film 23 may be provided in at least a portion of at least one of the first gap region G1 and the second gap region G2 in the electrode finger extending direction.

Examples in which the position of the addition film 23 is different from that in the first example embodiment will be described in a second example embodiment and a third example embodiment. Note that the acoustic wave devices according to the second example embodiment and the third example embodiments have the same configuration as the acoustic wave device 10 according to the first example embodiment except for the position of the addition film 23 in each gap region. That is, also in the second example embodiment and the third example embodiment, the addition film 23 having a higher dielectric constant and a higher density than silicon oxide is provided in the pair of gap regions. This can reduce or prevent an increase in insertion loss, as in the first example embodiment. In addition, the piston mode is established, and the transverse mode can be suppressed.

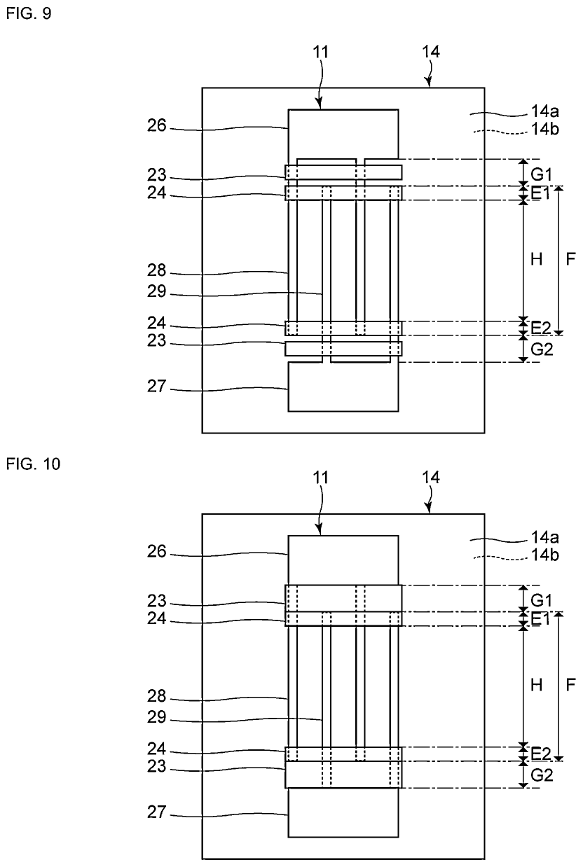

FIG. 9 is a schematic plan view of an acoustic wave device according to the second example embodiment.

In the present example embodiment, the addition film 23 provided in the first gap region G1 does not reach any of the end portion on the first busbar 26 side and the end portion on the intersection region F side in the first gap region G1. Similarly, the addition film 23 provided in the second gap region G2 does not reach any of the end portion on the second busbar 27 side and the end portion on the intersection region F side in the second gap region G2.

FIG. 10 is a schematic plan view of an acoustic wave device according to the third example embodiment.

In the present example embodiment, the addition film 23 provided in the first gap region G1 reaches both the end portion on the first busbar 26 side and the end portion on the intersection region F side in the first gap region G1. Similarly, the addition film 23 provided in the second gap region G2 reaches both the end portion on the second busbar 27 side and the end portion on the intersection region F side in the second gap region G2.

In the first to third example embodiments, the piezoelectric layer is a Z-cut lithium niobate layer. However, in other example embodiments of the present invention, the piezoelectric layer may be a lithium niobate layer other than the Z-cut. For example, preferably, the Euler angles (φ, θ, ψ) are within a range of about 0°±5°, within a range of about −8°±14°, and within a range of about 90°±5°, or within a range of about 0°±5°, within a range of about −8°±14°, and within a range of about 90°±5°. This makes it possible to increase a value of a fractional bandwidth. This will be described in detail below. Note that the fractional bandwidth is represented by (|fa−fr|/fr)×100 [%], where fr is a resonant frequency and fa is an anti-resonant frequency.

Examples of a plurality of acoustic wave devices 1 having the configuration of the first example embodiment illustrated in FIG. 1 and having different θ values of the Euler angles (φ, θ, ψ) of the piezoelectric layer 14 were prepared. Note that in each of the above acoustic wave devices 1, φ of the Euler angles (φ, θ, ψ) of the piezoelectric layer 14 is set to 0°, and ψ is set to 90°. The fractional bandwidth of each of the acoustic wave devices 1 was measured.

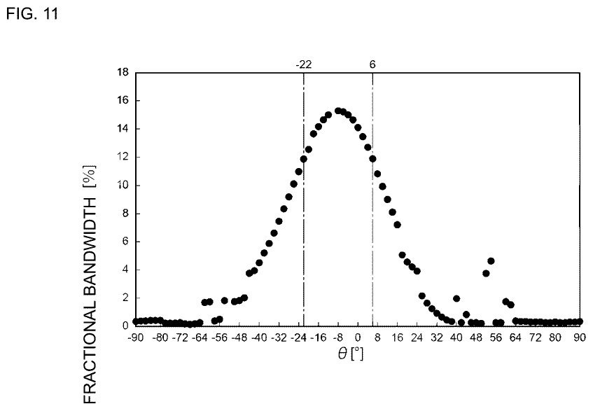

FIG. 11 is a graph illustrating a relationship between θ and a fractional bandwidth in the Euler angles (0°, θ, 90°).

As illustrated in FIG. 11, it is discovered and confirmed that the value of the fractional bandwidth is particularly large when θ in the Euler angles (0°, θ, 90°) is about −22°≤θ≤6°, for example. That is, when θ is within the range of −8°±14°, the value of the fractional bandwidth is particularly large. It is known that the fractional bandwidth does not vary significantly even when φ in the Euler angles (φ, θ, ψ) of the piezoelectric layer 14 is changed in the range of 0°±5°. Similarly, it is known that even when ψ is changed within the range of 90°±5°, there is no significant difference in the fractional bandwidth. From the above, the piezoelectric layer 14 is preferably a lithium niobate layer having the Euler angles (φ, θ, ψ) within the range of about 0°±5°, within the range of about −8°±14°, and within the range of about 90°±5°. Alternatively, the piezoelectric layer 14 is preferably a lithium niobate layer having the Euler angles (φ, θ, ψ) within the range of about 0°±5°, within the range of about −8°±14°, and within the range of about 90°±5°, for example. This makes it possible to increase the value of the fractional bandwidth.

The thickness-shear mode will be described in detail below. Note that the “electrode” in the IDT electrode described below corresponds to an electrode finger. The support in the following examples corresponds to a support substrate.

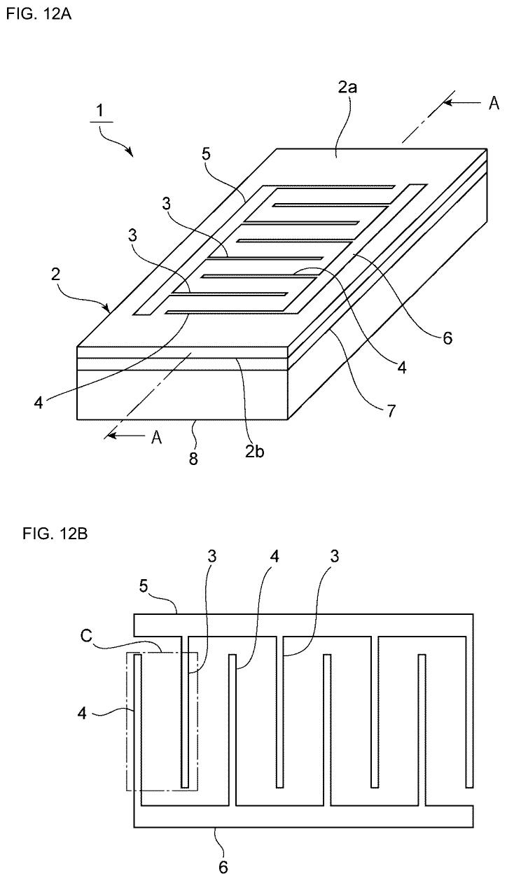

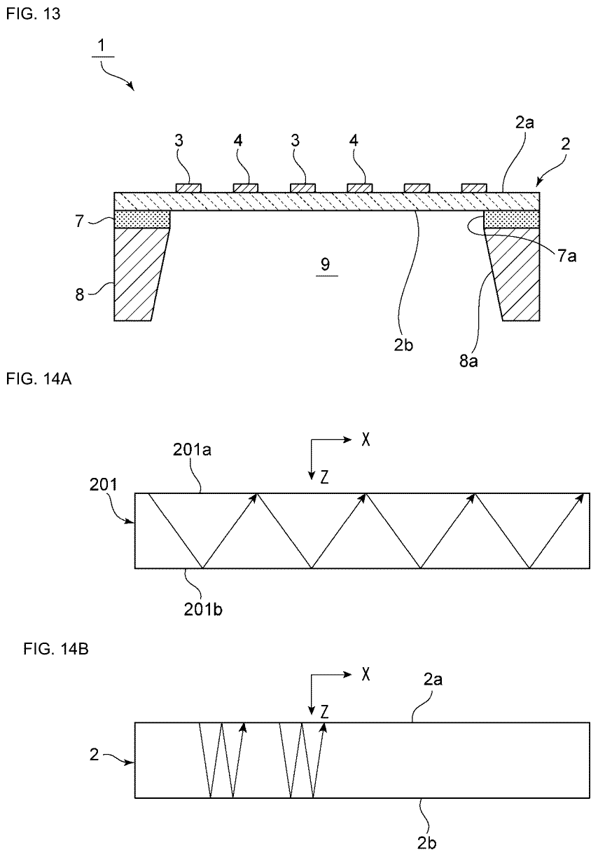

FIG. 12A is a schematic perspective view illustrating an appearance of an acoustic wave device using a bulk wave in a thickness-shear mode, FIG. 12B is a plan view illustrating an electrode structure on a piezoelectric layer, and FIG. 13 is a cross-sectional view of a portion taken along line A-A in FIG. 12A.

The acoustic wave device 1 includes a piezoelectric layer 2 made of LiNbO₃. The piezoelectric layer 2 may be made of LiTaO₃. The cut angle of the LiNbO₃ or LiTaO₃ is Z-cut, but may be rotated Y-cut or X-cut. A thickness of the piezoelectric layer 2 is not particularly limited, but is preferably equal to or more than about 40 nm and equal to or less than about 1000 nm, and more preferably equal to or more than about 50 nm and equal to or less than about 1000 nm, for example in order to effectively excite the thickness-shear mode. The piezoelectric layer 2 includes first and second main surfaces 2a and 2b opposite to each other. Electrodes 3 and 4 are provided on the first main surface 2a. Here, the electrode 3 is an example of a “first electrode”, and the electrode 4 is an example of a “second electrode”. In FIGS. 12A and 12B, the plurality of electrodes 3 includes a plurality of first electrode fingers connected to a first busbar 5. The plurality of electrodes 4 includes a plurality of second electrode fingers connected to a second busbar 6. The plurality of electrodes 3 and the plurality of electrodes 4 are interdigitated with each other. The electrodes 3 and 4 each have a rectangular shape and a length direction. The electrode 3 and the adjacent electrode 4 are opposite to each other in a direction orthogonal to the length direction. Each of a length direction of the electrodes 3 and 4 and a direction orthogonal to the length direction of the electrodes 3 and 4 is a direction intersecting a thickness direction of the piezoelectric layer 2. Therefore, it can be said that the electrode 3 and the adjacent electrode 4 are opposite to each other in the direction intersecting the thickness direction of the piezoelectric layer 2. In addition, the length direction of the electrodes 3 and 4 may be switched with the direction orthogonal to the length direction of the electrodes 3 and 4 illustrated in FIGS. 12A and 12B. That is, in FIGS. 12A and 12B, the electrodes 3 and 4 may be extended in the direction in which the first busbar 5 and the second busbar 6 extend. In this case, the first busbar 5 and the second busbar 6 extend in the direction in which the electrodes 3 and 4 extend in FIGS. 12A and 12B. A plurality of pairs of structures each having the electrode 3 connected to one potential and the electrode 4 connected to the other potential adjacent to each other is provided in the direction orthogonal to the length direction of the electrodes 3 and 4. Here, the expression “the electrode 3 and the electrode 4 being adjacent to each other” means that the electrode 3 and the electrode 4 are not arranged so as to be in direct contact with each other, but the electrode 3 and the electrode 4 are arranged with an interval therebetween. In addition, when the electrode 3 and the electrode 4 are adjacent to each other, no electrode connected to a hot electrode or a ground electrode, including the other electrodes 3 and 4, is arranged between the electrode 3 and the electrode 4. The number of pairs is not necessarily an integer pair, and may be 1.5 pairs, 2.5 pairs, or the like. A center-to-center distance between the electrodes 3 and 4, i.e., the pitch, is preferably in a range of equal to or more than about 1 μm and equal to or less than about 10 μm, for example. In addition, widths of each of the electrodes 3 and 4, that is, dimensions of each of the electrodes 3 and 4 in the opposing direction is preferably in a range of equal to or more than about 50 nm and equal to or less than about 1000 nm, and more preferably in a range of equal to or more than about 150 nm and equal to or less than about 1000 nm, for example. Note that the center-to-center distance between the electrodes 3 and 4 is a distance between the center of the dimension (width dimension) of the electrode 3 in the direction orthogonal to the length direction of the electrode 3 and the center of the dimension (width dimension) of the electrode 4 in the direction orthogonal to the length direction of the electrode 4.

In addition, in the acoustic wave device 1, since the Z-cut piezoelectric layer is used, the direction orthogonal to the length direction of the electrodes 3 and 4 is a direction orthogonal to a polarization direction of the piezoelectric layer 2. This is not the case when a piezoelectric material having a different cut angle is used as the piezoelectric layer 2. Here, the term “orthogonal” is not limited to being strictly orthogonal, and may be substantially orthogonal (the angle formed by the direction orthogonal to the length direction of the electrodes 3 and 4 and the polarization direction is, for example, within a range of about 90°±10°).

A support 8 is stacked on the second main surface 2b side of the piezoelectric layer 2 with an insulating layer 7 interposed therebetween. The insulating layer 7 and the support 8 each have a frame shape, and have a through-hole 7a and a through-hole 8a respectively as illustrated in FIG. 13. Thus, a cavity portion 9 is formed. The cavity portion 9 is structured and positioned not to hinder the vibration of an excitation region C of the piezoelectric layer 2. Therefore, the support 8 is stacked on the second main surface 2b with the insulating layer 7 interposed therebetween at a position not overlapping the portion where at least the pair of electrodes 3 and 4 are provided. Note that the insulating layer 7 need not be provided. Therefore, the support 8 can be directly or indirectly stacked on the second main surface 2b of the piezoelectric layer 2.

The insulating layer 7 may be made of silicon oxide. However, in addition to silicon oxide, an appropriate insulating material such as silicon oxynitride or alumina can be used. The support 8 is made of Si. A plane orientation of Si on the surface on the piezoelectric layer 2 side may be (100), (110), or (111). Si included in the support 8 is desirably high in resistance with a resistivity of equal to or more than about 4 kΩcm, for example. However, the support 8 may also be made of an appropriate insulating material or a semiconductor material.

As the material of the support 8, for example, a piezoelectric material such as aluminum oxide, lithium tantalate, lithium niobate, or quartz, various ceramics such as alumina, magnesia, sapphire, silicon nitride, aluminum nitride, silicon carbide, zirconia, cordierite, mullite, steatite, or forsterite, a dielectric such as diamond or glass, or a semiconductor such as gallium nitride can be used.

The plurality of electrodes 3 and 4 and the first and second busbars 5 and 6 are made of an appropriate metal or an alloy such as Al or an AlCu alloy. In the present example embodiment, the electrodes 3 and 4 and the first and second busbars 5 and 6 have a structure in which an Al film is stacked on a Ti film. Note that an adhesion layer other than the Ti film may be used.

In driving, an AC voltage is applied between the plurality of electrodes 3 and the plurality of electrodes 4. More specifically, an AC voltage is applied between the first busbar 5 and the second busbar 6. As such, it is possible to obtain resonance characteristics using a bulk wave in a thickness-shear mode excited in the piezoelectric layer 2. In addition, in the acoustic wave device 1, d/p is equal to or less than about 0.5, for example, where d is the thickness of the piezoelectric layer 2 and p is the center-to-center distance between any adjacent electrodes 3 and 4 of the plurality of pairs of electrodes 3 and 4. Therefore, the bulk wave in the above thickness-shear mode is effectively excited, and good resonance characteristics can be obtained. More preferably, d/p is equal to or less than about 0.24, for example, and in this case, even better resonance characteristics can be obtained.

Since the acoustic wave device 1 has the above-described configuration, even when the number of pairs of the electrodes 3 and 4 is reduced in order to achieve miniaturization, a Q value is unlikely to be reduced. This is because propagation loss is small even when the number of electrode fingers in the reflectors on both sides is reduced. In addition, the number of electrode fingers can be reduced because a bulk wave in a thickness-shear mode is used. The difference between the Lamb wave used in the acoustic wave device and the bulk wave in the thickness-shear mode will be described with reference to FIGS. 14A and 14B.

FIG. 14A is a schematic elevational cross-sectional view for explaining a Lamb wave propagating through a piezoelectric film of an acoustic wave device as described in Japanese Unexamined Patent Application Publication No. 2012-257019. The wave propagates, here, in a piezoelectric film 201 as indicated by arrows. Here, in the piezoelectric film 201, a first main surface 201a and a second main surface 201b are opposite to each other, and the thickness direction connecting the first main surface 201a and the second main surface 201b is a Z direction. An X direction is a direction in which the electrode fingers of the IDT electrode are arranged. As illustrated in FIG. 14A, in the Lamb wave, the wave propagates in the X direction as illustrated in the figure. Although the piezoelectric film 201 vibrates as a whole because of a plate wave, the wave propagates in the X direction, and thus reflectors are arranged on both sides to obtain resonance characteristics. Therefore, the propagation loss of the wave occurs, and when miniaturization is achieved, that is, when the number of pairs of electrode fingers is reduced, the Q value is reduced.

In contrast, as illustrated in FIG. 14B, in the acoustic wave device 1, the vibration is displaced in the thickness-shear direction, and thus the wave propagates substantially in the direction connecting the first main surface 2a and the second main surface 2b of the piezoelectric layer 2, that is, in the Z direction, and resonates. That is, the X-direction component of the wave is significantly smaller than the Z-direction component. Since the resonance characteristics are obtained by the propagation of the wave in the Z direction, the propagation loss is hardly generated even when the number of electrode fingers of the reflector is reduced. Further, even when the number of electrode pairs of the electrodes 3 and 4 is reduced in order to achieve the miniaturization, the Q value is less likely to be reduced.

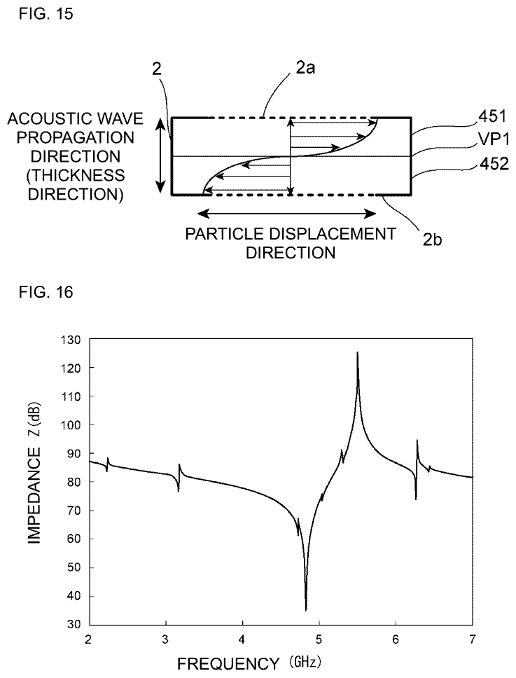

Note that as illustrated in FIG. 15, amplitude directions of the bulk wave in the thickness-shear mode are reversed between a first region 451 included in the excitation region C of the piezoelectric layer 2 and a second region 452 included in the excitation region C. FIG. 15 schematically illustrates the bulk wave in the case where a voltage is applied between the electrode 3 and the electrode 4 so that the electrode 4 has a higher potential than the electrode 3. The first region 451 is a region of the excitation region C between the first main surface 2a and a virtual plane VP1 that is orthogonal to the thickness direction of the piezoelectric layer 2 and divides the piezoelectric layer 2 into two portions. The second region 452 is a region of the excitation region C between the virtual plane VP1 and the second main surface 2b.

As described above, in the acoustic wave device 1, at least one pair of electrodes of the electrode 3 and the electrode 4 is arranged, but since the wave is not propagated in the X direction, the number of pairs of electrodes of the electrodes 3 and 4 does not need to be plural. That is, it is sufficient that at least one pair of electrodes is provided.

For example, the electrode 3 is an electrode connected to a hot potential, and the electrode 4 is an electrode connected to a ground potential. However, the electrode 3 may be connected to the ground potential, and the electrode 4 may be connected to the hot potential. In the present example embodiment, as described above, at least one pair of electrodes is an electrode connected to the hot potential or an electrode connected to the ground potential, and no floating electrode is provided.

FIG. 16 is a graph illustrating the resonance characteristics of the acoustic wave device illustrated in FIG. 13. Note that examples of design parameters of the acoustic wave device 1 having the resonance characteristics are as follows.

Piezoelectric layer 2: LiNbO₃ with Euler angles (0°, 0°, 90°), thickness=400 nm.

When viewed in the direction orthogonal to the length direction of the electrode 3 and the electrode 4, the region in which the electrode 3 and the electrode 4 overlap, i.e., a length of the excitation region C=40 μm, the number of pairs of electrodes 3 and 4=21, the center-to-center distance between the electrodes=3 μm, the width of the electrodes 3 and 4=500 nm, and d/p=0.133.

Insulating layer 7: a silicon oxide film having a thickness of 1 μm.

Support 8: Si.

Note that the length of the excitation region C is a dimension of the excitation region C along the length direction of the electrodes 3 and 4.

In the present example embodiment, distances between electrodes of the electrode pairs including the electrodes 3 and 4 were all equal in the plurality of pairs. That is, the electrodes 3 and the electrodes 4 were arranged at an equal pitch.

As is clear from FIG. 16, although the reflector is not provided, the favorable resonance characteristics with the fractional bandwidth of about 12.5%, for example, are obtained.

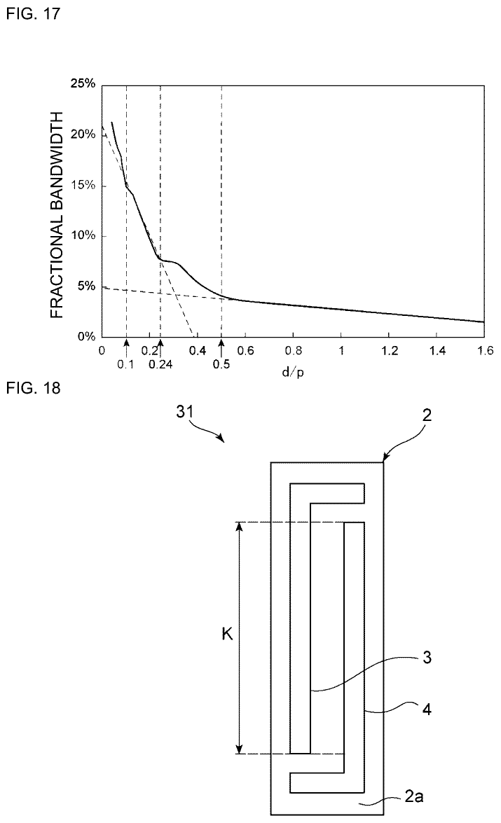

As described above, in the present example embodiment, d/p is equal to or less than about 0.5, and more preferably equal to or less than about 0.24, for example, where d is the thickness of the piezoelectric layer 2 and p is the center-to-center distance between the electrode 3 and the electrode 4. This will be described with reference to FIG. 17.

A plurality of acoustic wave devices was obtained in the same manner as the acoustic wave device having the resonance characteristics illustrated in FIG. 16, except that d/p was changed. FIG. 17 is a graph illustrating a relationship between d/p and the fractional bandwidth of the resonator of the acoustic wave device.

As is clear from FIG. 17, when d/p>about 0.5 is satisfied, for example, the fractional bandwidth is less than about 5% even when d/p is adjusted. In contrast, in the case of d/p about 0.5, the fractional bandwidth can be increased to equal to or more than about 5% by changing d/p within the range, for example, and thus, a resonator having a high coupling coefficient can be provided. In addition, when d/p is equal to or less than about 0.24, the fractional bandwidth can be increased to equal to or more than about 7%, for example. In addition, when d/p is adjusted within this range, a resonator having a wider fractional bandwidth can be obtained, and a resonator having a higher coupling coefficient can be realized. Therefore, it is understood that a resonator having a high coupling coefficient using the bulk wave in the thickness-shear mode can be generated by setting d/p to be equal to or less than about 0.5, for example.

FIG. 18 is a plan view of an acoustic wave device using the bulk wave in the thickness-shear mode. In an acoustic wave device 31, a pair of electrodes including the electrode 3 and the electrode 4 is provided on the first main surface 2a of the piezoelectric layer 2. Note that in FIG. 18, K is an intersection width. As described above, in an acoustic wave device according to an example embodiment of the present invention, the number of pairs of electrodes may be one. Also in this case, when the above d/p is equal to or less than about 0.5, for example, the bulk wave in the thickness-shear mode can be effectively excited.

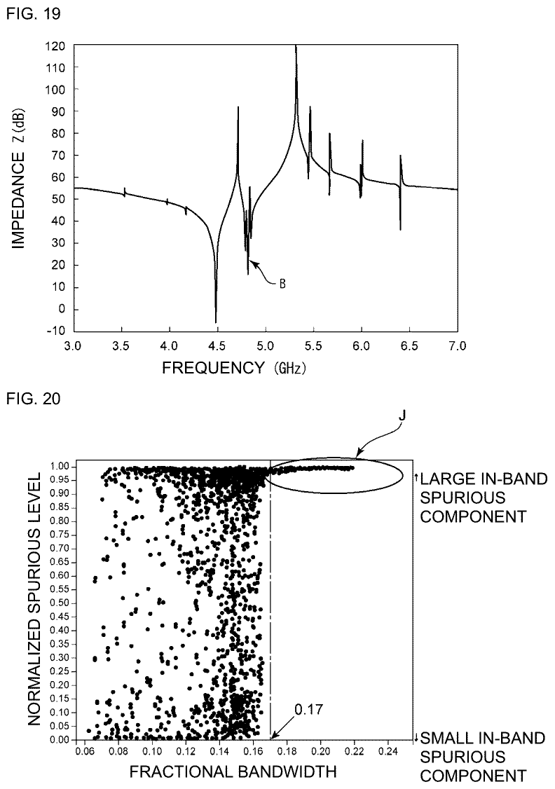

Preferably, in the plurality of electrodes 3 and 4 in the acoustic wave device 1, it is desirable that, with respect to the excitation region C in which any adjacent electrodes 3 and 4 overlap each other when viewed in the direction in which the electrodes 3 and 4 are opposite to each other, a metallization ratio MR of the adjacent electrodes 3 and 4 satisfies MR about 1.75 (d/p)+0.075, for example. In this case, spurious emission can be effectively reduced. This will be described with reference to FIG. 19 and FIG. 20. FIG. 19 is a reference diagram illustrating an example of the resonance characteristics of the acoustic wave device 1. Spurious response indicated by an arrow B appears between the resonant frequency and the anti-resonant frequency. Note that d/p=about 0.08 and the Euler angles of LiNbO₃ were set to (0°, 0°, 90°), for example. In addition, the metallization ratio MR was set to about 0.35, for example.

The metallization ratio MR will be described with reference to FIG. 12B. In the electrode structure of FIG. 12B, when attention is paid to one pair of electrodes 3 and 4, it is assumed that only the one pair of electrodes 3 and 4 is provided. In this case, a portion surrounded by a dash-dotted line is the excitation region C. The excitation region C is a region overlapping the electrode 4 in the electrode 3, a region overlapping the electrode 3 in the electrode 4, and a region where the electrode 3 and the electrode 4 overlap each other in a region between the electrode 3 and the electrode 4, when the electrode 3 and the electrode 4 are viewed in the direction orthogonal to the length direction of the electrodes 3 and 4, that is, in the opposing direction. The area of the electrodes 3 and 4 in the excitation region C with respect to the area of the excitation region C is the metallization ratio MR. That is, the metallization ratio MR is the ratio of the area of the metallization portion with respect to the area of the excitation region C.

Note that when a plurality of pairs of electrodes is provided, the ratio of the metallization portion included in the entire excitation region with respect to the total area of the excitation region may be defined as MR.

FIG. 20 is a graph illustrating a relationship between the fractional bandwidth and a phase rotation amount of impedance of a spurious mode normalized by 180 degrees as magnitude of the spurious emission when a large number of acoustic wave resonators are formed according to the present example embodiment. Note that the fractional bandwidth was adjusted by changing a film thickness of the piezoelectric layer and the dimension of the electrode. Further, FIG. 20 shows the results in the case of using the piezoelectric layer formed of the Z-cut LiNbO₃, but the same tendency is obtained in the case of using the piezoelectric layer having another cut angle.

In the region surrounded by an ellipse J in FIG. 20, the spurious level is as large as about 1.0, for example. As is clear from FIG. 20, when the fractional bandwidth exceeds about 0.17, that is, when the fractional bandwidth exceeds about 17%, for example, large spurious emission having a spurious level of 1 or more appears in the pass band even when parameters defining the fractional bandwidth are changed. That is, as in the resonance characteristics illustrated in FIG. 19, a large spurious response indicated by the arrow B appears in the band. Therefore, the fractional bandwidth is preferably equal to or less than about 17%, for example. In this case, the spurious emission can be reduced by adjusting the film thickness of the piezoelectric layer 2 and the dimension of the electrodes 3 and 4.

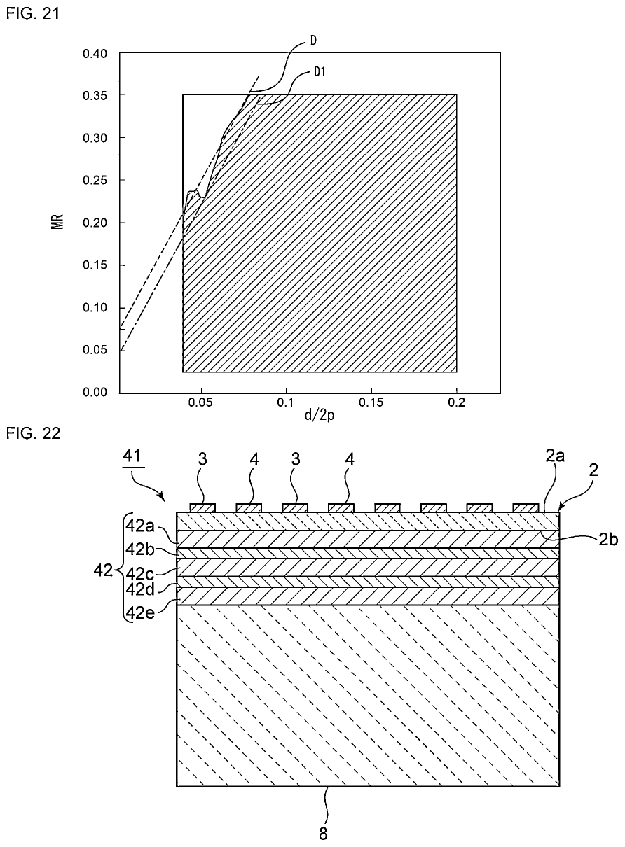

FIG. 21 is a graph illustrating a relationship between d/2p, the metallization ratio MR, and the fractional bandwidth. In the above acoustic wave device, various acoustic wave devices having different d/2p and MR were formed, and the fractional bandwidth was measured. The hatched portion on the right side of a broken line D in FIG. 21 is the region in which the fractional bandwidth is equal to or less than about 17%, for example. A boundary between the hatched region and the unhatched region is represented by MR=about 3.5 (d/2p)+0.075, for example. That is, MR=about 1.75 (d/p)+0.075 is satisfied, for example. Therefore, preferably, MR about 1.75 (d/p)+0.075 is satisfied, for example. In this case, the fractional bandwidth is easily set to equal to or less than about 17%, for example. More preferably, it is a region on the right side of a portion: MR=about 3.5 (d/2p)+0.05, for example, indicated by a dash-dotted line Dl in FIG. 21. That is, when MR about 1.75 (d/p)+0.05 is satisfied, the fractional bandwidth can be reliably set to equal to or less than about 17%, for example.

FIG. 22 is an elevational cross-sectional view of an acoustic wave device including an acoustic multilayer film.

In an acoustic wave device 41, an acoustic multilayer film 42 is stacked on the second main surface 2b of the piezoelectric layer 2. The acoustic multilayer film 42 has a stacked structure of low acoustic impedance layers 42a, 42c, and 42e each having relatively low acoustic impedance and high acoustic impedance layers 42b and 42d each having relatively high acoustic impedance. When the acoustic multilayer film 42 is used, the bulk wave in the thickness-shear mode can be confined in the piezoelectric layer 2 without using the cavity portion 9 in the acoustic wave device 1. Also in the acoustic wave device 41, the resonance characteristics based on the bulk wave in the thickness-shear mode can be obtained by setting the above d/p to be equal to or less than about 0.5, for example. Note that in the acoustic multilayer film 42, the number of stacking of the low acoustic impedance layers 42a, 42c, and 42e and the number of stacking the high acoustic impedance layers 42b and 42d are not particularly limited. It is sufficient that at least one of the high acoustic impedance layers 42b and 42d is located farther from the piezoelectric layer 2 than the low acoustic impedance layers 42a, 42c, and 42e.

The low acoustic impedance layers 42a, 42c, and 42e and the high acoustic impedance layers 42b and 42d may be made of any appropriate material as long as the above-described relationship of acoustic impedances is satisfied. For example, the material of the low acoustic impedance layers 42a, 42c, and 42e may be silicon oxide, silicon oxynitride, or the like. In addition, the material of the high acoustic impedance layers 42b and 42d may be alumina, silicon nitride, metals, or the like.

In the acoustic wave devices according to the first to third example embodiments, for example, the acoustic multilayer film 42 illustrated in FIG. 22 may be provided between the support substrate and the piezoelectric layer. In this case, the acoustic multilayer film 42 may be formed by alternately stacking the low acoustic impedance layers and the high acoustic impedance layers. The acoustic multilayer film 42 may be an acoustic reflector portion in the acoustic wave device.

In the acoustic wave devices of the first to third example embodiments using the bulk wave in the thickness-shear mode, as described above, d/p is preferably equal to or less than about 0.5, and more preferably equal to or less than about 0.24, for example. This makes it possible to obtain further improved resonance characteristics. Furthermore, in the intersection region in the acoustic wave devices according to the first to third example embodiments that use the bulk wave in the thickness-shear mode, as described above, MR about 1.75 (d/p)+0.075 is preferably satisfied. In this case, spurious emission can be suppressed more reliably.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including a support substrate;
a piezoelectric layer on the support and including a lithium niobate layer or a lithium tantalate layer; and
an IDT electrode on the piezoelectric layer and including a pair of busbars and a plurality of electrode fingers; wherein
the support includes an acoustic reflector portion overlapping at least a portion of the IDT electrode in plan view;
when a thickness of the piezoelectric layer is defined as d and a center-to-center distance between the electrode fingers adjacent to each other is defined as p, d/p is equal to or less than about 0.5;
some electrode fingers of the plurality of electrode fingers are connected to one busbar of the IDT electrode, remaining electrode fingers of the plurality of electrode fingers are connected to another busbar, the plurality of electrode fingers connected to the one busbar and the plurality of electrode fingers connected to the other busbar being interdigitated with each other;
when viewed from a direction in which the adjacent electrode fingers are opposite to each other, a region in which the adjacent electrode fingers overlap each other is an intersection region, and a region located between the intersection region and the pair of busbars is a pair of gap regions; and
an addition film with a higher dielectric constant and a higher density than silicon oxide is provided in at least one of the pair of gap regions.

2. The acoustic wave device according to claim 1, wherein the addition film is included in each of the pair of gap regions.

3. The acoustic wave device according to claim 1, wherein the piezoelectric layer is a lithium niobate layer having Euler angles (φ, θ, ψ) within a range of about 0°±5°, within a range of about −8°±14°, and within a range of about 90°±5°, or within a range of about 0°±5°, within a range of about −8°±14°, and within a range of about 90°±5°.

4. The acoustic wave device according to claim 1, wherein the addition film includes at least one dielectric selected from a group consisting of tungsten oxide, niobium pentoxide, tantalum oxide, or hafnium oxide.

5. The acoustic wave device according to claim 1, wherein the addition film is located on at least one of the electrode fingers.

6. The acoustic wave device according to claim 5, wherein the addition film is located on the piezoelectric layer so as to cover the plurality of electrode fingers.

7. The acoustic wave device according to claim 1, wherein the addition film extends to, of an end portion on the busbar side and an end portion on the intersection region side, the end portion on the intersection region side in the gap region in which the addition film is provided.

8. The acoustic wave device according to claim 1, wherein a thickness of the addition film is equal to or more than about 5 nm and equal to or less than about 20 nm.

9. The acoustic wave device according to claim 1, wherein
when a direction in which the plurality of electrode fingers extends is defined as an electrode finger extending direction, the intersection region includes a central region and a pair of edge regions sandwiching the central region in the electrode finger extending direction; and
a mass addition film is located in at least one of the pair of edge regions.

10. The acoustic wave device according to claim 9, wherein the mass addition film is a silicon oxide film.

11. The acoustic wave device according to claim 9, wherein the mass addition film is made of a same material as the addition film.

12. The acoustic wave device according to claim 1, wherein the acoustic reflector portion includes a cavity in the support.

13. The acoustic wave device according to claim 1, wherein d/p is equal to or less than about 0.24.

14. The acoustic wave device according to claim 1, wherein, when a metallization ratio of the plurality of electrode fingers with respect to the intersection region is defined as MR, MR about 1.75 (d/p)+0.075 is satisfied.

15. The acoustic wave device according to claim 1, wherein the support includes an insulating layer on the support substrate, and the piezoelectric layer is on the insulating layer.

16. The acoustic wave device according to claim 15, wherein the support substrate includes a semiconductor material or a ceramic material, and the insulating layer includes a dielectric material.

17. The acoustic wave device according to claim 1, wherein the acoustic wave device is one of an acoustic wave resonator, a filter, or a multiplexer.

18. The acoustic wave device according to claim 1, wherein the acoustic wave device is structured to generate a bulk wave in a thickness-shear mode.

19. The acoustic wave device according to claim 12, wherein at least a portion of the IDT electrode overlaps the cavity.

20. The acoustic wave device according to claim 1, wherein the acoustic reflector portion includes an acoustic multilayer film.
